(19) United States
(12) Patent Application Publication
(10) Pub. No.: US 2026/0181991 A1
(43) Pub. Date: Jun. 25, 2026

(54) SEMICONDUCTOR MEMORY DEVICE

(71) Applicant: Samsung Electronics Co., Ltd., Suwon-si (KR)

(72) Inventors: Ho In LEE, Suwon-si (KR); Jin Yeong KIM, Suwon-si (KR); Sei-Ryung CHOI, Suwon-si (KR)

(21) Appl. No.: 19/317,489

(22) Filed: Sep. 3, 2025

(30) Foreign Application Priority Data
Dec. 23, 2024 (KR) 10-2024-0194327

(51) Int. Cl. H10D 64/27; H10B 12/00

(52) U.S. Cl. CPC H10D 64/513; H10B 12/315; H10B 12/482; H10B 12/488

(57) ABSTRACT

A semiconductor memory device includes a substrate provided with a plurality of active regions, wherein each active region of the plurality of active regions extends lengthwise in a first direction; and an isolation film disposed on the substrate and defining each active region of the plurality of active regions. Each active region of the plurality of active regions includes: a first expansion and a second expansion, which are opposite to each other in the first direction; and a connector connecting the first expansion to the second expansion and having a varying width in a second direction perpendicular to the first direction. A maximum width, in the second direction, of each of the first expansion and the second expansion is greater than a minimum width, in the second direction, of the connector.

### CROSS-REFERENCE TO RELATED APPLICATION

This application claims priority from Korean Patent Application No. 10-2024-0194327 filed on Dec. 23, 2024 in the Korean Intellectual Property Office, and all the benefits accruing therefrom under 35 U.S.C. 119, the contents of which in its entirety are herein incorporated by reference.

### BACKGROUND

### 1. Field

The present disclosure relates to a semiconductor memory device.

### 2. Description of the Related Art

As semiconductor devices become increasingly integrated, individual circuit patterns are being miniaturized to implement a greater number of semiconductor devices within the same area. As the integration density of semiconductor devices increases, the design rules for the components of semiconductor devices are being reduced.

In highly scaled semiconductor devices, the process of forming multiple wiring lines and multiple buried contacts (BCs) interposed between the wiring lines is becoming increasingly complex and challenging.

### SUMMARY

An objective of the present disclosure is to provide a semiconductor memory device capable of improving reliability and performance.

The objectives of the present disclosure are not limited to those mentioned above, and other objectives not explicitly stated will be clearly understood by those skilled in the art based on the following description.

According to an aspect of the present disclosure, a semiconductor memory device includes a substrate provided with a plurality of active regions, wherein each active region of the plurality of active regions extends lengthwise in a first direction, and an isolation film disposed on the substrate and defining each active region of the plurality of active regions. Each active region of the plurality of active regions includes a first expansion and a second expansion, which are opposite to each other in the first direction, and a connector connecting the first expansion to the second expansion and having a varying width in a second direction perpendicular to the first direction. A maximum width, in the second direction, of each of the first expansion and the second expansion is greater than a minimum width, in the second direction, of the connector.

According to an aspect of the present disclosure, a semiconductor memory device includes a substrate provided with a plurality of active regions, wherein each active region of the plurality of active regions extends lengthwise in a first direction. Each active region of the plurality of active regions includes a first expansion and a second expansion, which are opposite to each other in the first direction, and a connector connecting the first expansion to the second expansion and having a varying width in a second direction perpendicular to the first direction. The connector includes a first portion connected to the first expansion, a second portion connected to the second expansion, and a third portion between the first portion and the second portion. A width, in the second direction, of the third portion is greater than a width of each of the first portion and the second portion.

According to an aspect of the present disclosure, a semiconductor memory device includes a substrate provided with a plurality of active regions, wherein each active region of the plurality of active regions has a long axis in a first direction and a short axis in a second direction perpendicular to the first direction, an isolation film disposed on the substrate and defining each active region of the plurality of active regions, a plurality of wordlines disposed within the substrate and extending in a third direction, a plurality of bitlines disposed on the substrate and extending in a fourth direction perpendicular to the third direction, and a plurality of data storage patterns on the substrate. Each active region of the plurality of active regions includes a first expansion and a second expansion, which are opposite to each other in the first direction, and a connector connecting the first expansion to the second expansion and having a varying width in the second direction. When viewed in a plan view, each of the first expansion and the second expansion has a semicircular shape. At a boundary between the first expansion and the connector, a width, in the second direction, of the first expansion is greater than a width, in the second direction, of the connector. At a boundary between the second expansion and the connector, a width, in the second direction, of the second expansion is greater than the width, in the second direction, of the connector. For a first active region of the plurality of active regions, corresponding two data storage patterns among the plurality of data storage patterns are electrically connected to a first expansion and a second expansion of the first active region.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a layout diagram of a semiconductor memory device according to some embodiments;

FIG. 2 is a layout illustrating an active region, a first isolation film, and a second isolation film of FIG. 1;

FIG. 3 is a cross-sectional view taken along line A-A of FIG. 1;

FIG. 4 is a cross-sectional view taken along line B-B of FIG. 1;

FIG. 5 is a layout diagram of a semiconductor memory device according to some embodiments;

FIG. 6 is a cross-sectional view taken along line B-B of FIG. 5;

FIGS. 7 through 18 are diagrams illustrating intermediate stages of a method for manufacturing a semiconductor memory device according to some embodiments; and

FIGS. 19 through 21 are diagrams illustrating intermediate stages of a method for manufacturing a semiconductor memory device according to some embodiments.

### DETAILED DESCRIPTION

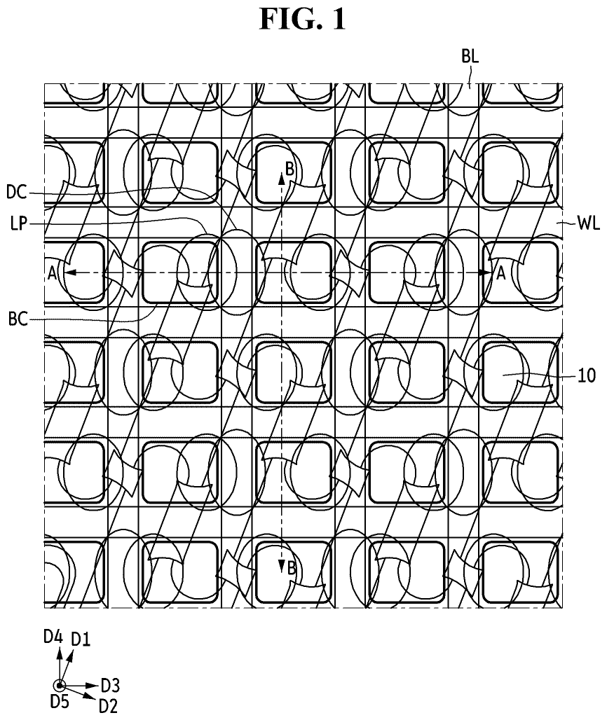

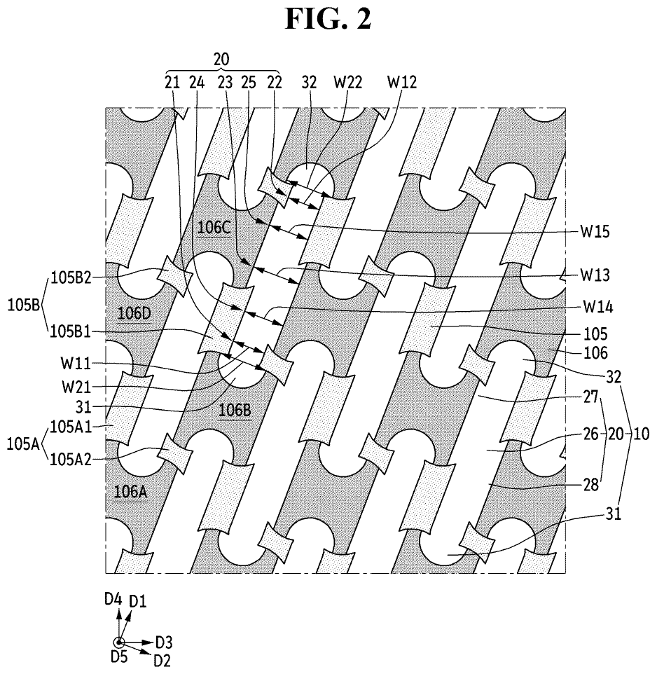

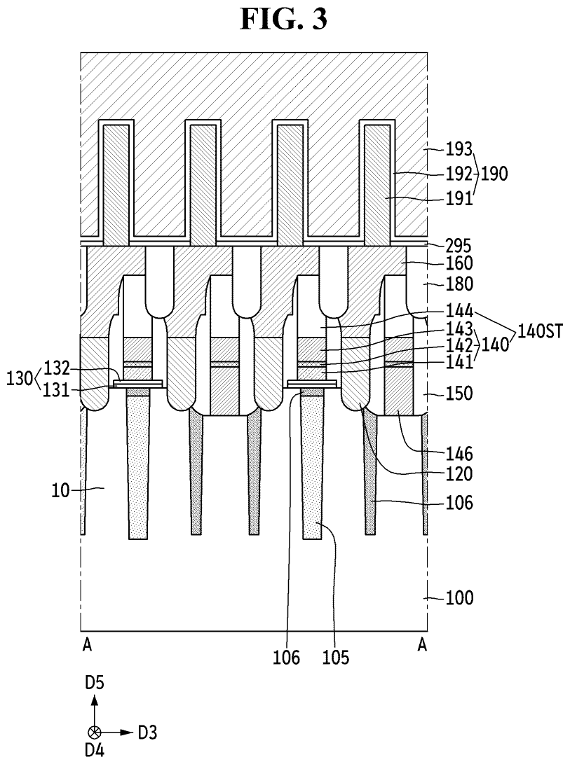

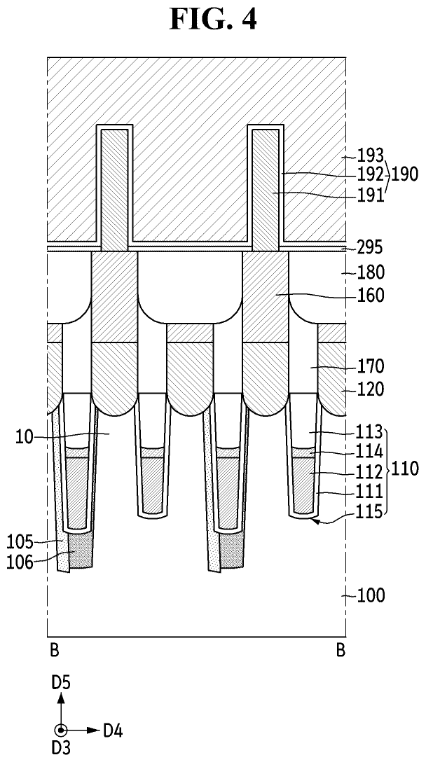

FIG. 1 is a layout diagram of a semiconductor memory device according to some embodiments. FIG. 2 is a layout illustrating the active region, the first isolation film, and the second isolation film of FIG. 1. FIG. 3 is a cross-sectional view taken along line A-A of FIG. 1. FIG. 4 is a cross-sectional view taken along line B-B of FIG. 1.

The drawings of the semiconductor memory device according to some embodiments illustrate a dynamic random-access memory (DRAM) as an example, but the present disclosure is not limited thereto.

Referring to FIGS. 1 and 2, the semiconductor memory device according to some embodiments includes active regions 10 and isolation films (105 and 106).

A substrate 100 in FIGS. 3 and 4 may be provided with the active regions 10 which may be defined by isolation films 105 and 106. The isolation films 105 and 106 may be formed within the substrate 100 in FIGS. 3 and 4. In an embodiment, the active regions 10 may include active fins. The active fins may be formed by partially etching the substrate 100 or may be epitaxially formed from the substrate 100. As the design rules of the semiconductor memory device according to some embodiments decrease, the active regions 10, as illustrated, may be arranged in the form of diagonal or oblique bars. For example, the active regions 10 may extend lengthwise in a first direction D1. The active regions 10 may be spaced apart from one another.

A fourth direction D4 may be orthogonal to a third direction D3. A second direction D2 may be orthogonal to the first direction D1. The first direction D1 may be a direction between the third and fourth directions D3 and D4. A fifth direction D5 may be orthogonal to the first, second, third, and fourth directions D1, D2, D3, and D4. The fifth direction D5 may be perpendicular to an upper surface of the substrate 100. Upper and lower surfaces may be defined based on the fifth direction D5. For example, the first to fourth directions D1 to D4 may be in the same plane, and the fifth direction D5 may be perpendicular to the plane.

Each of the active regions 10 includes a first expansion 31, a second expansion 32, and a connector 20 sequentially connected along the first direction D1.

The first and second expansions 31 and 32 are opposite ends of the corresponding active region 10 in the first direction D1. The first and second expansions 31 and 32 may have a convex shape in the first direction D1. From a planar perspective (e.g., from the perspective of a plane including the first, second, third, and fourth directions D1, D2, D3, and D4) (i.e., when viewed in a plan view), the first and second expansions 31 and 32 may have a semicircular shape. For example, when viewed in a plan view, a circumferential surface of the first expansion 31 may be connected to the isolation film 105 (i.e., a first pair of first isolation films 105A), and may have a semicircular shape. Similarly, when viewed in a plan view, a circumferential surface of the second expansion 32 may be connected to the isolation film 105 (i.e., a second pair of first isolation films 105B), and may have a semicircular shape.

The connector 20 connects the first and second expansions 31 and 32. At the boundary between the connector 20 and the first expansion 31, the width of the first expansion 31 in the second direction D2 is greater than the width of the connector 20 in the second direction D2. Similarly, at the boundary between the connector 20 and the second expansion 32, the width of the second expansion 32 in the second direction D2 is greater than the width of the connector 20 in the second direction D2.

The connector 20 may include a body 26, a first extension 27, and a second extension 28.

The body 26 may extend in the first direction D1. The body 26 may have a bar shape extending lengthwise in the first direction D1. The body 26 may have an elongated island shape, including a long axis and a short axis. The body 26 may have an oblique shape, forming an angle of less than 90 degrees with wordlines WL extending in the third direction D3. The long axis of the body 26 may be in the first direction D1, and the short axis of the body 26 may be in the second direction D2.

The first expansion 31 may be connected to a first end of the body 26 in the first direction D1, and the second expansion 32 may be connected to a second end of the body 26 opposite to the first end in the first direction D1.

The first extension 27 may extend along at least a portion of a first side of the body 26 in the second direction D2. The second extension 28 may extend along at least a portion of a second side of the body 26, opposite the first side, in the second direction D2. The first and second extensions 27 and 28 may be spaced apart from the first and second expansions 31 and 32. A portion of the first extension 27 may overlap a portion of the second extension 28 in the second direction D2. The first extension 27 may include a portion that overlaps the second extension 28 in the second direction D2 and a portion that does not overlap the second extension portion 28 in the second direction D2. The second extension 28 may include a portion that overlaps the first extension 27 in the second direction D2 and a portion that does not overlap the first extension 27 in the second direction D2.

Opposite sides of each of the first and second extensions 27 and 28 in the first direction D1 may be rounded. The width of each of the first and second extensions 27 and 28 in the first direction D1 may increase away from the body 26.

The connector 20 includes a first portion 21, a second portion 22, a third portion 23, a fourth portion 24, and a fifth portion 25. The first portion 21 may be connected to the first expansion 31. For example, the first portion 21 may correspond to a portion of the connector 20 between the first pair of first isolation films 105A in the second direction D2. The second portion 22 may be connected to the second expansion 32. For example, the second portion 22 may correspond to a portion of the connector 20 between the second pair of first isolation films 105B in the second direction D2. The third portion 23 may be disposed between the first and second expansions 31 and 32. The fourth portion 24 may connect the first and third portions 21 and 23. The fifth portion 25 may connect the second and third portions 22 and 23. The first pair of first isolation films 105A may include a first-first isolation film 105A1 and a second-first isolation film 105A2. The fourth portion 24 may correspond to a portion of the connector 20 between the first-first isolation film 105A1 and the second isolation film 106 (e.g., a second-second isolation film 106B, which will be described below) in the second direction D2. The second pair of isolation films 105B may include a first-second isolation film 105B1 and a second-second isolation film 105B2. The fifth portion 25 may correspond to a portion of the connector 20 between the first-second isolation film 105B1 and the second isolation film 106 (e.g., a fourth-second isolation film 106D, which will be described below) in the second direction D2. The third portion 23 that is disposed between the fourth portion 24 and the fifth portion 25 in the first direction D1 may correspond to a portion of the connector 20 between two opposite portions of the second isolation film 106 (e.g., the second-second isolation film 106B and the fourth-second isolation film 106D) in the second direction D2.

That is, the first portion 21, the fourth portion 24, the third portion 23, the fifth portion 25, and the second portion 22 may be sequentially connected along the first direction D1. The first and second portions 21 and 22 may form a first portion and a second portion of the body 26. The third portion 23 may include a third portion of the body 26, a first portion the first extension 27, and a first portion of the second extension 28. The first portion of the first extension 27 and the first portion of the second extension 28 may overlap each other in the second direction D2. The fourth portion 24 may include a fourth portion of body 26 and a second portion of the second extension 28 which overlap each other in the second direction D2. The fifth portion 25 may include a fifth portion of the body 26 and a second portion of the first extension 27 which overlap each other in the second direction D2.

In the second direction D2, a maximum width W21 of the first expansion 31 and a maximum width W22 of the second expansion 32 are greater than a width W11 of the first portion 21 and a width W12 of the second portion 22. In the second direction D2, a width W13 of the third portion 23 is greater than the widths W11 and W12 of the first and second portions 21 and 22. In the second direction D2, the width W13 of the third portion 23 is also greater than a width W14 of the fourth portion 24 and a width W15 of the fifth portion 25. In the second direction D2, the widths W14 and W15 of the fourth and fifth portions 24 and 25 are greater than the widths W11 and W12 of the first and second portions 21 and 22. Additionally, in the second direction D2, the maximum widths W21 and W22 of the first and second expansions 31 and 32 are greater than the minimum width (e.g., W11 and/or W12) of the connector 20.

The isolation films (105 and 106) may be formed within the substrate 100. The isolation films (105 and 106) may have a shallow trench isolation (STI) structure that provides excellent device isolation characteristics. The isolation films (105 and 106) may define the active regions 10 within a memory cell region.

The isolation films (105 and 106) may include first isolation films 105 and second isolation films 106. For example, each active region may be defined by four first isolation films 105 and four second isolation films 106. Each of the four first isolation films 105 and each of four second isolation films 106 may be alternately connected in a counterclockwise direction to define the active region. For each active region, the four first isolation films 105 may include the first-first isolation film 105A1, the second-first isolation film 105A2, the first-second isolation film 105B1, and the second-second isolation 105B2 which are arranged in the counterclockwise direction, and the four second isolation films 106 may include a first-second isolation film 106A, a second-second isolation film 106B, a third-second isolation film 106C, and a fourth-second isolation film 106D which are arranged in the counterclockwise. In an embodiment, the first-first isolation film 105A1 and the first-second isolation film 105B1 may have the same shape, and the second-first isolation film 105A2 and the second-second isolation film 105B2 may have the same shape. A length, in the first direction D1, of each of the first-first isolation film 105A1 and the first-second isolation film 105B1 may be greater than a length, in the first direction D1, of each of the second-first isolation film 105A2 and the second-second isolation film 105B2. In an embodiment, the first-second isolation film 106A, the second-second isolation film 106B, the third-second isolation film 106C, and the fourth-second isolation film 106D may have the same shape. Each of the first-second isolation film 106A, the second-second isolation film 106B, the third-second isolation film 106C, and the fourth-second isolation film 106D may be shared by four adjacent active regions, and therefore may be interchangeably referred to depending on which of the four active regions is being referenced. For example, the second-second isolation film 106B for a specific active region may be referred to as a first-second isolation film 106 for an active region adjacent thereto and sharing the first-second isolation film 105B1.

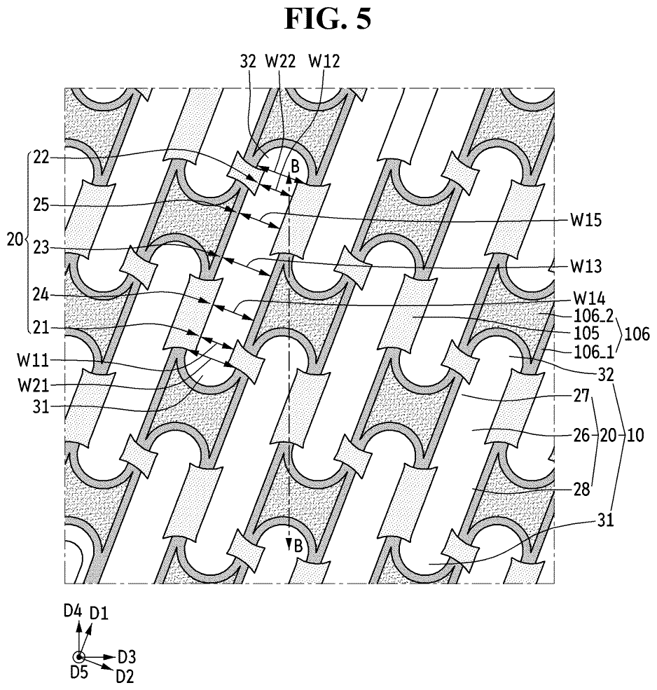

The first isolation films 105 may include, for example, at least one of a silicon oxide film, a silicon nitride film, and a silicon oxynitride film. The second isolation films 106 may include, for example, at least one of a silicon oxide film, a silicon nitride film, and a silicon oxynitride film. In an embodiment, the first isolation films 105 and the second isolation films 106 may be formed of the same insulating material. For example, the first isolation films 105 and the second isolation films 106 may be a silicon oxide film, a silicon nitride film, or a silicon oxynitride film. The present disclosure is not limited thereto. For example, an insulating material of the first isolation films 105 may differ from an insulating material of the second isolation films 106. In some embodiments, each of the second isolation films 106 may be a single layer. The present disclosure is not limited thereto. In an embodiment, each of the second isolation films 106 may include two or more layers as shown in FIG. 5, which will be described later.

Opposite side surfaces of the bodies 26 of the active regions 10 in the second direction D2 may be defined by the first isolation films 105. For example, the first pair of first isolation films 105A and the second pair of first isolation films 105B may protrude into an inside of the active region 10. A side surface of the first-first isolation film 105A1 extending in the first direction D1, a side surface of the second-second isolation film 105B2 extending in the first direction D1, and a first imaginary line connecting the side surface of the first-first isolation film 105A1 and the side surface of the second-second isolation film 105B2 and extending in the first direction D1 may constitute a first side surface of the body 26. In an embodiment, the first imaginary line, the side surface of the first-first isolation film 105A1, and the side surface of the second-second isolation film 105B2 may be aligned along a straight line extending in the first direction D1. A side surface of the second-first isolation film 105A2 extending in the first direction D1, a side surface of the first-second isolation film 105B1 extending in the first direction D1, and a second imaginary line connecting the side surface of the second-first isolation film 105A2 and the side surface of first-second isolation film 105B1 and extending in the first direction D1 may constitute a second side surface of the body 26 which is opposite to the first side surface of the body 26 in the second direction D2. In an embodiment, the second imaginary line, the side surface of the second-first isolation film 105A2, and the side surface of first-second isolation film 105B1 may be aligned along a straight line extending in the first direction. Opposite side surfaces of the first extensions 27 of the active regions 10 in the first direction D1 may be defined by the first isolation films 105 (e.g., the first-first isolation film 105A1 and the second-second isolation film 105B2). Opposite side surfaces of the second extensions 28 of the active regions 10 in the first direction D1 may also be defined by the first isolation films 105 (e.g., the second-first isolation film 105A2 and the first-second isolation film 105B1). The side surfaces of the first extensions 27 of the active regions 10 in the second direction D2 and the side surfaces of the second extensions 28 of the active regions 10 in the second direction D2 may be defined by the second isolation films 106. For example, in each active region 10, a side surface of the first extension 27 may be defined by the second isolation film 106 (e.g., the fourth-second isolation film 106D), and a side surface of the second extension 28 may be defined by the second isolation film 106 (e.g., the second-second isolation film 106B). The first expansions 31 and second expansions 32 of the active regions 10 may be defined by the first isolation films 105 and the second isolation films 106. In each active region 10, the first expansion 31 may be defined by the first-second isolation film 106A and the first pair of first isolation films 105A, and the second expansion 32 may be defined by the third-second isolation film 106C and the second pair of first isolation films 105B.

A plurality of gate electrodes extending across the active regions 10 in the third direction D3 may be disposed. The plurality of gate electrodes may extend parallel to one another. For example, the plurality of gate electrodes may correspond to a plurality of wordlines WL. The wordlines WL may be arranged at regular intervals along the fourth direction D4. The width of the wordlines WL and the spacing between the wordlines WL may be determined based on design rules. From a planar perspective (e.g., from the perspective of the plane including the first, second, third, and fourth directions D1, D2, D3, and D4), the wordlines WL may be spaced apart from the first expansions 31 and second expansions 32 of the active regions 10.

The active regions 10 may each be divided into three parts by two wordlines WL extending in the third direction D3. The active regions 10 may each include storage connection regions and a bitline connection region. The bitline connection region may be located at the central portion of the corresponding active region 10, and the storage connection regions may be located at opposite ends of the corresponding active region 10. The bitline connection region may include at least portions of the third and/or fourth parts 23 and 24 of the corresponding active region 10 and at least a portion of the fifth part 25 of the corresponding active region 10, and the storage connection regions may include at least portions of the first expansion 31 and/or the first part 21 of the corresponding active region 10 and at least portions of the second expansion 32 and/or the second part 22 of the corresponding active region 10.

For example, the bitline connection region may correspond to a region connected to a bitline BL, and the storage connection regions may correspond to regions connected to a data storage pattern (190 in FIGS. 3 and 4). In other words, the bitline connection region may correspond to a common drain region, and the storage connection regions may correspond to source regions. Each of the wordlines WL, and the bitline connection region and storage connection regions adjacent thereto may form a transistor.

A plurality of bitlines BL extending in the fourth direction D4, perpendicular to the wordlines WL, may be disposed over the wordlines WL. The bitlines BL may extend parallel to one another. The bitlines BL may be arranged at regular intervals along the third direction D3. The width of the bitlines BL and the spacing between the bitlines BL may be determined based on design rules.

The semiconductor memory device according to some embodiments may include various contact arrangements formed on the active regions 10. The various contact arrangements may include, for example, direct contacts DC, buried contacts BC, and landing pads LP.

The direct contacts DC may refer to contacts electrically connecting the active regions 10 to the bitlines BL. The buried contacts BC may refer to contacts connecting the active regions 10 to lower electrodes (191 in FIG. 3) of data storage patterns 190. The contact area between the buried contacts BC and the active regions 10 may be small due to their arrangement. Accordingly, conductive landing pads LP may be introduced to increase the contact area between the active regions 10 and the lower electrodes 191 of the data storage patterns 190.

The landing pads LP may be disposed between the active regions 10 and the buried contacts BC or between the buried contacts BC and the lower electrodes 191 of the data storage patterns 190. In the semiconductor memory device according to some embodiments, the landing pads LP may be disposed between the buried contacts BC and the lower electrodes 191 of the data storage patterns 190. By introducing the landing pads LP, the contact area can be increased and contact resistance between the active regions 10 and the lower electrodes of the capacitors may be decreased.

The direct contacts DC may be connected to the bitline connection regions of the active regions 10. The buried contacts BC may be connected to the storage connection regions of the active regions 10. As the buried contacts BC are disposed at opposite ends of the active regions 10 (e.g., the first expansions 31 and/or the first parts 21, and the second expansions 32 and/or the second parts 22), the landing pads LP may be disposed adjacent to the opposite ends of the active regions 10, partially overlapping the buried contacts BC. The buried contacts BC may overlap the active regions 10 and the isolation films (105 and 106), between adjacent wordlines WL and between adjacent bitlines BL.

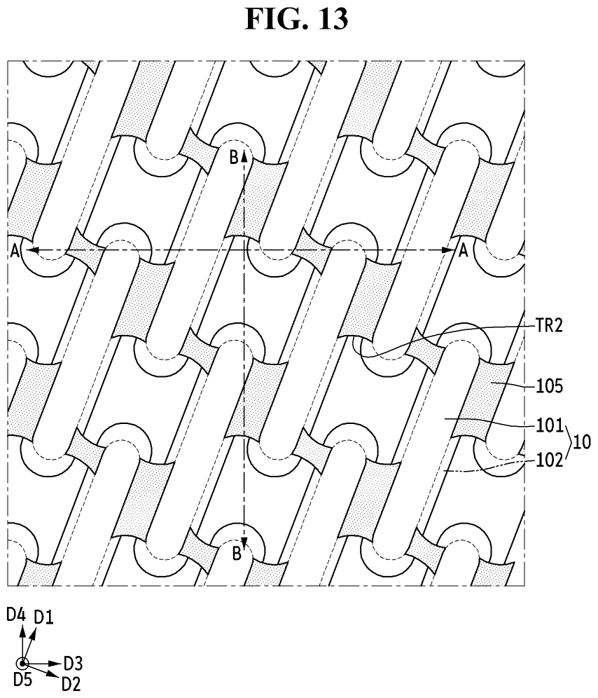

In the semiconductor memory device according to some embodiments, the buried contacts BC may be connected to the relatively wider first and second expansions 31 and 32 of the active regions 10. For example, the first expansions 31 and the second expansions 32 may include opposite ends of a conventional active region and additional regions epitaxially grown from opposite ends of the conventional active region, which will be discussed with reference to FIG. 13. The first expansions 31 and the second expansions 32 may provide an increased contact area for the buried contacts BC compared to the conventional active region. The buried contacts BC may contact the relatively wider first and second expansions 31 and 32 of the active regions 10 compared to the conventional active regions. Consequently, the contact area between the buried contacts BC and the active regions 10 may increase, providing a memory device with improved reliability.

The wordlines WL may be formed to be buried within the substrate 100. The wordlines WL may extend across the active regions 10 between the direct contacts DC or between the buried contacts BC. As illustrated, two wordlines WL may extend across a single active region 10. As the active regions 10 extend in the first direction D1, the wordlines WL may form an angle of less than 90 degrees with the active regions 10.

The direct contacts DC and the buried contacts BC may be symmetrically arranged. Thus, the direct contacts DC and the buried contacts BC may be aligned in straight lines extending along the third and fourth directions D3 and D4. In contrast, the landing pads LP may be arranged in a zigzag fashion along the fourth direction D4, in which the bitlines BL extend. Additionally, along the third direction D3, in which the wordlines WL extend, the landing pads LP may overlap the same side portions of the respective bitlines BL.

For example, a first row of landing pads LP may overlap the left sides of the corresponding bitlines BL, and a second row of landing pads LP may overlap the right sides of the corresponding bitlines BL.

Referring to FIGS. 1 through 4, the semiconductor memory device according to some embodiments may include the active regions 10, a plurality of gate structures 110, a plurality of conductive lines 140, a plurality of storage pads 160, and the data storage patterns 190.

The substrate 100 may be a silicon (Si) substrate or a silicon-on-insulator (SOI). Alternatively, the substrate 100 may include silicon-germanium, silicon germanium-on-insulator (SGOI), indium antimonide, a lead telluride compound, indium arsenide, indium phosphide, gallium arsenide, or gallium antimonide, but is not limited thereto.

In FIG. 3, the upper surfaces of the isolation films (105 and 106) and the substrate 100 are illustrated as lying in the same plane, but are not limited thereto. Due to manufacturing process considerations, the height levels of the upper surfaces of the isolation films (105 and 106) illustrated in FIG. 3 may differ from those illustrated in FIG. 4.

In FIG. 3, the second isolation films 106 are illustrated as formed on the upper surfaces of the first isolation films 105, but are not limited thereto. Alternatively, the second isolation films 106 may not be formed on the upper surfaces of the first isolation films 105, and the upper surfaces of the first isolation films 105 may lie in the same plane as the upper surface of the substrate 100.

In the fifth direction D5, the depth of the first isolation films 105 may differ from that of the second isolation films 106. The lowermost surfaces of the first isolation films 105 may lie on a plane different from that of the lowermost surfaces of the second isolation films 106. The lowermost surfaces of the first isolation films 105 may lie below the lowermost surfaces of the second isolation films 106.

The gate structures 110 may be formed within the substrate 100 and the isolation films (105 and 106). The gate structures 110 may be formed across the active regions 10 defined by the isolation films (105 and 106).

The gate structures 110 may extend in the third direction D3. The gate structures 110 may be spaced apart from each other in the fourth direction D4.

The gate structures 110 may each include a gate trench 115 formed in the substrate 100 and the isolation films (105 and 106), a gate insulating film 111, a gate electrode 112, a gate capping pattern 113, and a gate capping conductive film 114. The gate electrodes 112 of the gate structures 110 may correspond to the wordlines WL.

The gate trenches 115 of the gate structures 110 may be disposed within the substrate 100 and the isolation films (105 and 106). The gate trenches 115 may be arranged across the active regions 10. The gate trenches 115 may extend longitudinally in the third direction D3.

The bottom surfaces of the gate trenches 115 may be curved. The gate trenches 115 may be relatively deep within the isolation films (105 and 106) and relatively shallow within the active regions 10. For example, the depth of the gate trenches 115 may be greater within the isolation films (105 and 106) than within the active regions 10. The lowermost ends of the gate trenches 115 formed in the isolation films (105 and 106) may be lower than the lowermost ends of the gate trenches 115 formed in the active regions 10.

Portions of the gate trenches 115 may be formed within the first isolation films 105, and other portions of the gate trenches 115 may be formed within the second isolation films 106. One side surface and a portion of the bottom surface of each of the gate trenches 115 may be defined by the first isolation films 105, and the other side surface and the remaining bottom surface of each of the gate trenches 115 may be defined by the second isolation films 106.

In an embodiment, the bottom surfaces of the gate trenches 115 within the first isolation films 105 and the bottom surfaces of the gate trenches 115 within the second isolation films 106 may lie in different planes.

The bitline connection regions of the active regions 10, the storage connection regions of the active regions 10, and the gate electrodes 112 of the gate structures 110 may form buried channel transistors.

The gate insulating films 111 of the gate structures 110 may extend along the sidewalls and bottom surfaces of the gate trenches 115. The gate insulating films 111 may extend along at least portions of the profiles of the gate trenches 115.

The gate insulating films 111 may include, for example, at least one of silicon oxide, silicon nitride, silicon oxynitride, and a high-k dielectric material with a dielectric constant greater than that of silicon oxide. Examples of the high-k dielectric material may include hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, or a combination thereof.

The gate electrodes 112 may be disposed on the gate insulating films 111. The gate electrodes 112 may partially fill the gate trenches 115.

The gate capping conductive films 114 may extend along the upper surfaces of the gate electrodes 112. In the semiconductor memory device according to some embodiments, the gate capping conductive films 114 may cover the entire upper surfaces of the gate electrodes 112.

The gate electrodes 112 may include a conductive material, for example, at least one of doped polysilicon, a conductive metal nitride, a conductive metal silicon nitride, a metal carbonitride, a conductive metal silicide, a conductive metal oxide, a two-dimensional (2D) material, a metal, and a metal alloy. The gate capping conductive films 114 may include, for example, polysilicon or polysilicon-germanium, but are not limited thereto.

The gate capping patterns 113 of the gate structures 110 may be disposed on the gate electrodes 112 and the gate capping conductive films 114. The gate capping patterns 113 may fill the remaining portions of the gate trenches 115 after the formation of the gate electrodes 112 and the gate capping conductive films 114. The gate insulating films 111 are illustrated as extending along the sidewalls of the gate capping patterns 113, but are not limited thereto.

The gate capping patterns 113 may include, for example, at least one of silicon nitride (SiN), silicon oxynitride (SiON), silicon dioxide (SiO₂), silicon carbonitride (SiCN), silicon oxycarbonitride (SiOCN), and a combination thereof.

Although not illustrated, impurity-doped regions may be formed on at least one side of the gate structures 110. The impurity-doped regions may correspond to the source/drain regions of transistors. The impurity-doped regions may be formed in the storage connection regions and the bitline connection regions.

Bitline structures 140ST may each include a conductive line 140 and a line capping film 144. The conductive lines 140 of the bitline structures 140ST may extend in the fourth direction D4. The conductive lines 140 may intersect the active regions 10 defined by the isolation films (105 and 106). The conductive lines 140 may correspond to the bitlines BL.

The conductive line 140 may include, for example, at least one of a doped semiconductor material, a conductive silicide compound, a conductive metal nitride, a 2D material, and a metal. In some embodiments of the semiconductor memory device, the 2D material may be a metallic or semiconductor material. The 2D material may include a 2D allotrope or a 2D compound, for example, at least one of graphene, molybdenum disulfide (MoS₂), molybdenum diselenide (MoSe₂), tungsten diselenide (WSe₂), and tungsten disulfide (WS₂), but is not limited thereto. That is, the aforementioned 2D materials are merely exemplary and do not limit the types of 2D materials that may be included in the semiconductor memory device according to some embodiments.

The conductive lines 140 may be single layers or double layers. Alternatively, as illustrated, the conductive lines 140 may be multilayers each including a first conductive line 141, a second conductive line 142, and a third conductive line 143. The conductive lines 140 are depicted as triple layers, but are not limited thereto. That is, the conductive lines 140 may include either single layers or stacks of multiple conductive layers.

The line capping films 144 of the bitline structures 140ST may be disposed on the conductive lines 140. The line capping films 144 may extend along the upper surfaces of the conductive lines 140 in the fourth direction D4. The line capping films 144 may each include, for example, at least one of a silicon nitride film, a silicon oxynitride film, a silicon carbonitride film, and a silicon oxycarbonitride film. In the semiconductor memory device according to some embodiments, the line capping films 144 may each include a silicon nitride film. The line capping films 144 are depicted as single layers, but are not limited thereto.

The bitline contacts 146 of the bitline structures 140ST may be disposed between the conductive lines 140 and the substrate 100. For example, the conductive lines 140 may be disposed on the bitline contacts 146. For example, the bitline contacts 146 may be disposed at locations where the conductive lines 140 intersect the central portions of the active regions 10 with an elongated island shape. The bitline contacts 146 may be disposed between the bitline connection regions of the active regions 10 and the conductive lines 140. The bitline contacts 146 may be connected to the bitline connection regions.

A plurality of bitline contacts 146 may be arranged along the fourth direction D4. The conductive lines 140 may be disposed on the bitline contacts 146 and may extend along the fourth direction D4.

The bitline contacts 146 may electrically connect the conductive lines 140 and the substrate 100. The bitline contacts 146 may correspond to the direct contacts DC. The bitline contacts 146 may include, for example, at least one of a doped semiconductor material, a conductive silicide compound, a conductive metal nitride, and a metal.

In FIG. 3, the thickness of the conductive lines 140 may be smaller in areas overlapping the upper surfaces of the bitline contacts 146 than in areas not overlapping the upper surfaces of the bitline contacts 146. In an embodiment, the thickness of the conductive lines 140 may be the same in both the areas overlapping the upper surfaces of the bitline contacts 146 and the areas not overlapping the upper surfaces of the bitline contacts 146.

Cell insulating films 130 may be disposed on the substrate 100 and the isolation films (105 and 106). For example, the cell insulating films 130 may be disposed on portions of the substrate 100 and the isolation films (105 and 106) where the bitline contacts 146 are not formed. The cell insulating films 130 may be disposed between the substrate 100 and the conductive lines 140, and between the isolation films (105 and 106) and the conductive lines 140. In the semiconductor memory device according to some embodiments, the upper surfaces of the bitline contacts 146 may be higher than the upper surfaces of the cell insulating films 130, relative to the upper surface of the substrate 100.

The cell insulating films 130 may be single layers. Alternatively, as illustrated, the cell insulating films 130 may be multilayers each including a first cell insulating film 131 and a second cell insulating film 132. For example, the first cell insulating film 131 may include, but is not limited to, a silicon oxide film, and the second cell insulating film 132 may include, but is not limited to, a silicon nitride film. In an embodiment, the cell insulating films 130 may each include three or more insulating films.

Spacers 150 may be disposed on the sidewalls of the conductive lines 140 and the line capping films 144. In portions of the conductive lines 140 where the bitline contacts 146 are formed, the spacers 150 may be formed on the substrate 100 and the isolation films (105 and 106). The spacers 150 may be disposed on the sidewalls of the conductive lines 140, the sidewalls of the line capping films 144, and the sidewalls of the bitline contacts 146.

In other portions of the conductive lines 140 where the bitline contacts 146 are not formed, the spacers 150 may be disposed on the cell insulating films 130. The spacers 150 may be disposed on the sidewalls of the conductive lines 140 and the line capping films 144.

The spacers 150 are depicted as single layers, but are not limited thereto. In an embodiment, the spacers 150 may have a multilayer structure. The spacers 150 may include, for example, at least one of silicon oxide, silicon nitride, silicon oxynitride, silicon oxycarbonitride, air, and a combination thereof.

Fence patterns 170 may be disposed on the substrate 100 and the isolation films (105 and 106). The fence patterns 170 may be disposed to overlap the gate structures 110, formed within the substrate 100 and the isolation films (105 and 106). The fence patterns 170 may be disposed on the gate capping patterns 113.

The fence patterns 170 may be disposed between the bitline structures 140ST, extending in the fourth direction D4. The fence patterns 170 may include, for example, at least one of silicon oxide, silicon nitride, silicon oxynitride, and a combination thereof.

A plurality of storage contacts 120 may be disposed between adjacent conductive lines 140 in the third direction D3. The storage contacts 120 may be disposed between adjacent fence patterns 170 in the fourth direction D4. The storage contacts 120 may overlap the substrate 100 and the isolation films (105 and 106), between the adjacent conductive lines 140 in the fifth direction D5. The storage contacts 120 may be connected to the storage connection regions of the active regions 10. The storage contacts 120 may correspond to the buried contacts BC.

The storage contacts 120 may include, for example, at least one of a doped semiconductor material, a conductive silicide compound, a conductive metal nitride, and a metal.

Storage pads 160 may be disposed on the storage contacts 120. The storage pads 160 may be electrically connected to the storage contacts 120. The storage pads 160 may be connected to the storage connection regions of the active regions 10. The storage pads 160 may correspond to the landing pads LP.

The storage pads 160 may overlap portions of the upper surfaces of the conductive lines 140. The storage pads 160 may include, for example, at least one of a doped semiconductor material, a conductive silicide compound, a conductive metal nitride, a conductive metal carbide, and a metal.

Pad isolation insulating films 180 may be disposed on the storage pads 160 and the conductive lines 140. For example, the pad isolation insulating films 180 may be disposed on the line capping films 144. The pad isolation insulating films 180 may define the storage pads 160 by forming a plurality of isolated regions. The pad isolation insulating films 180 may not cover the upper surfaces of the storage pads 160. The pad isolation insulating films 180 may fill pad isolation recesses. The pad isolation recesses may separate adjacent storage pads 160.

The pad isolation insulating films 180 may include an insulating material, and may electrically isolate the storage pads 160 from one another. For example, the pad isolation insulating film 180 may include at least one of silicon oxide, silicon nitride, silicon oxynitride, silicon oxycarbonitride, and silicon carbonitride, but is not limited thereto.

Etch stop films 295 may be disposed on the upper surfaces of the storage pads 160 and the pad isolation insulating films 180. The etch stop films 295 may include, for example, at least one of silicon nitride, silicon carbonitride, silicon oxycarbonitride, silicon oxycarbide, and silicon boron nitride.

The data storage patterns 190 may be disposed on the storage pads 160. The data storage patterns 190 may be connected to the storage pads 160. Portions of the data storage patterns 190 may be disposed within the etch stop films 295.

For example, the data storage patterns 190 may be capacitors. The data storage patterns 190 may include lower electrodes 191, a capacitor dielectric film 192, and an upper electrode 193. For example, the upper electrode 193 may be a plate-type upper electrode.

The lower electrodes 191 may be disposed on the storage pads 160. The lower electrodes 191 may, for example, have a pillar shape. The capacitor dielectric film 192 may be disposed on the lower electrodes 191. The capacitor dielectric film 192 may be formed along the profiles of the lower electrodes 191. The upper electrode 193 may be disposed on the capacitor dielectric film 192. The upper electrode 193 may surround the outer sidewalls of the lower electrodes 191. The upper electrode 193 is depicted as a single layer, but is not limited thereto. In an embodiment, the lower electrodes 191 may have an open-ended cylindrical shape.

The lower electrodes 191 and the upper electrode 193 may each include, for example, at least one of a doped semiconductor material, a conductive metal nitride (e.g., titanium nitride, tantalum nitride, niobium nitride, or tungsten nitride), a metal (e.g., ruthenium, iridium, titanium, or tantalum), and a conductive metal oxide (e.g., iridium oxide or niobium oxide), but are not limited thereto.

The capacitor dielectric film 192 may include, for example, at least one of silicon oxide, silicon nitride, silicon oxynitride, a high-k dielectric material, and a combination thereof, but is not limited thereto. The capacitor dielectric film 192 may include at least one of a ferroelectric material, an antiferroelectric material, and a paraelectric material. The capacitor dielectric film 192 may include, for example, one of a ferroelectric material, an antiferroelectric material, a paraelectric material, a combination of the ferroelectric and antiferroelectric materials, a combination of the ferroelectric and paraelectric materials, a combination of the paraelectric and antiferroelectric materials, and a combination of the ferroelectric, antiferroelectric, and paraelectric materials.

In the semiconductor device according to some embodiments, the capacitor dielectric film 192 may include a stacked film structure where zirconium oxide, aluminum oxide, and zirconium oxide are sequentially deposited. In the semiconductor device according to some embodiments, the capacitor dielectric film 192 may include a dielectric film containing hafnium (Hf).

Alternatively, the data storage patterns 190 may be variable resistance patterns capable of switching between two resistance states in response to electrical pulses applied to memory elements. For example, the data storage patterns 190 may include a phase-change material, a perovskite compound, a transition metal oxide, a magnetic material, a ferromagnetic material, or an antiferromagnetic material, whose a crystalline state changes depending on the level of current.

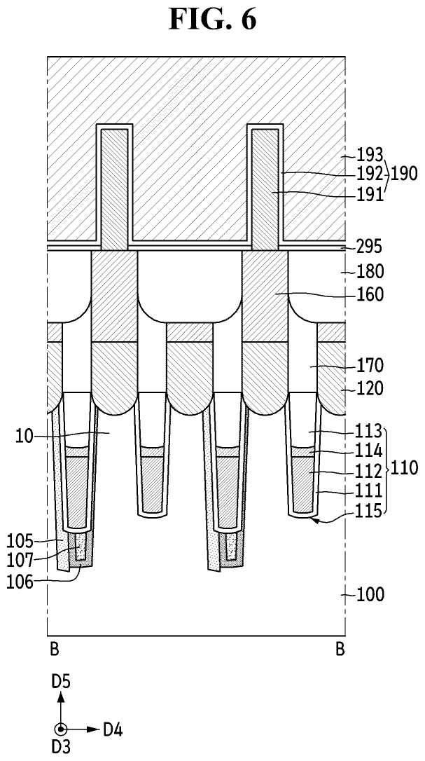

FIGS. 5 and 6 are diagrams for explaining a semiconductor memory device according to some embodiments. FIG. 5 is a diagram illustrating active regions, first isolation films, and second isolation films of the semiconductor memory device according to some embodiments. FIG. 6 is a cross-sectional view taken along line B-B of FIG. 5. Line B-B of FIG. 5 corresponds to line B-B of FIG. 1.

Referring to FIGS. 5 and 6, in the semiconductor memory device according to some embodiments, second isolation films 106 may be multilayers.

For example, the second isolation films 106 may each include a first film 106_1 and a second film 106_2. The second film 106_2 may be formed on the first film 106_1. The first film 106_1 may include a trench. The second film 106_2 may fill the trench in the first film 106_1.

The first and second films 106_1 and 106_2 may each include, for example, at least one of a silicon oxide film, a silicon nitride film, and a silicon oxynitride film, but are not limited thereto. In some embodiments, the first film 106_1 may include a silicon oxide film, and the second film 106_2 may include a silicon nitride film.

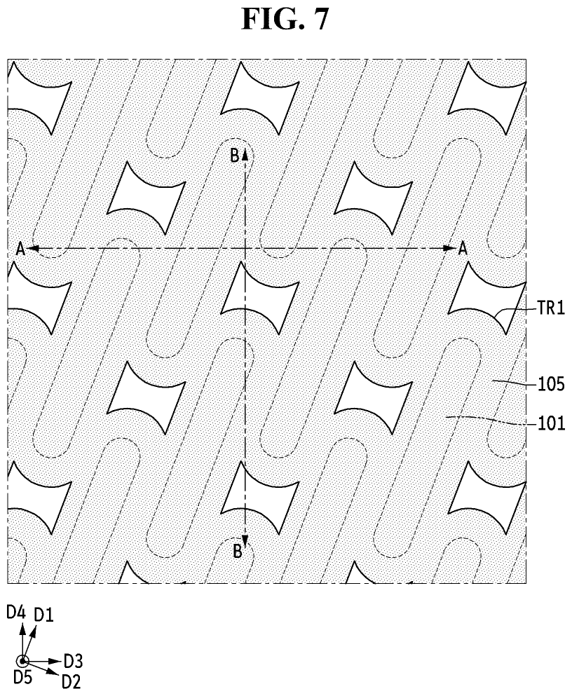

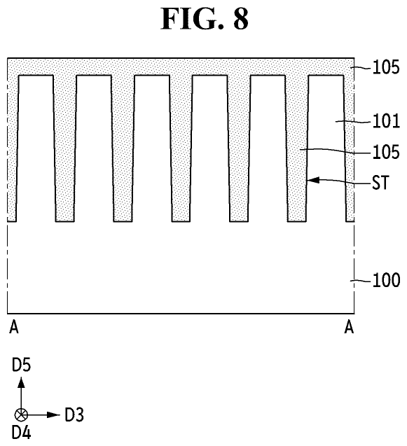

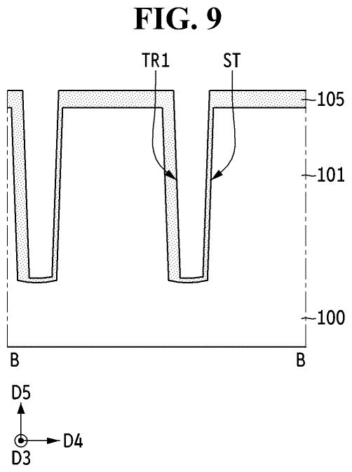

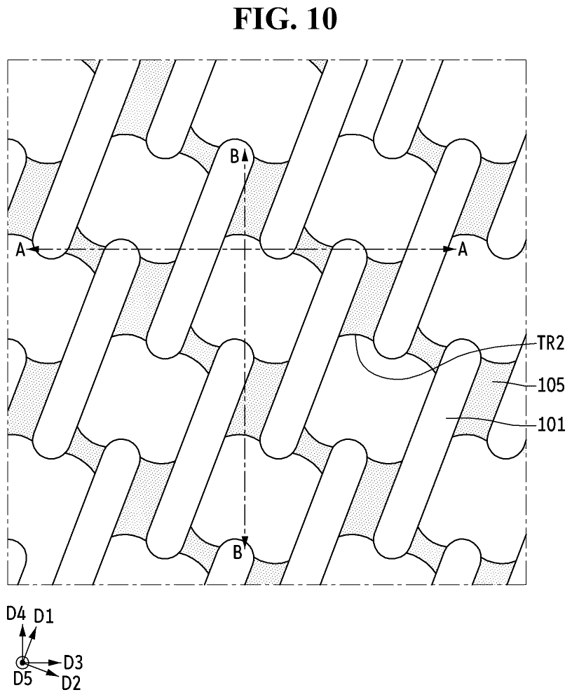

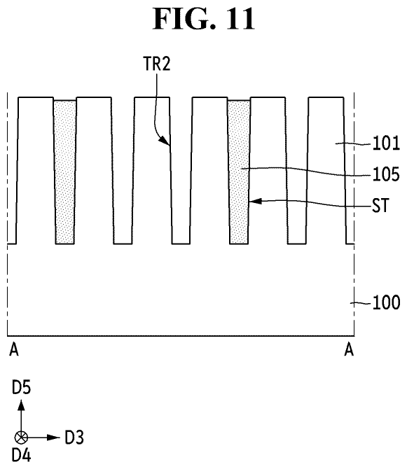

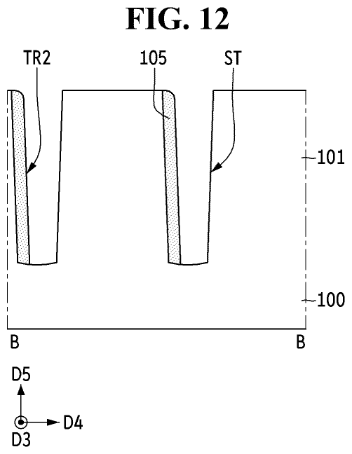

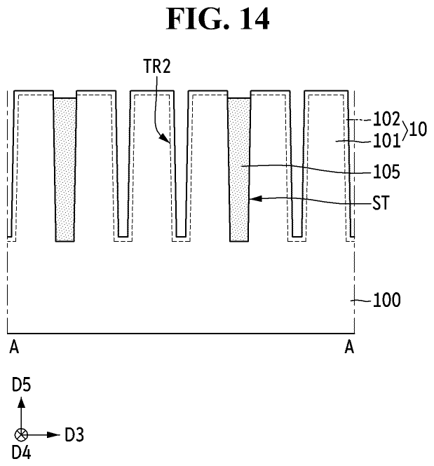

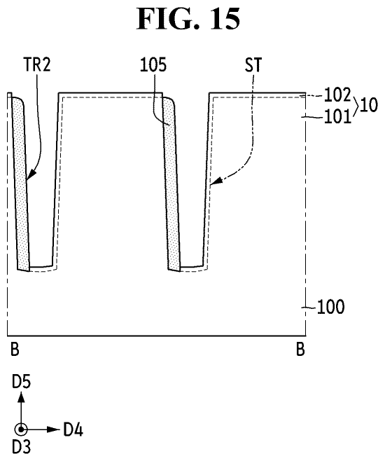

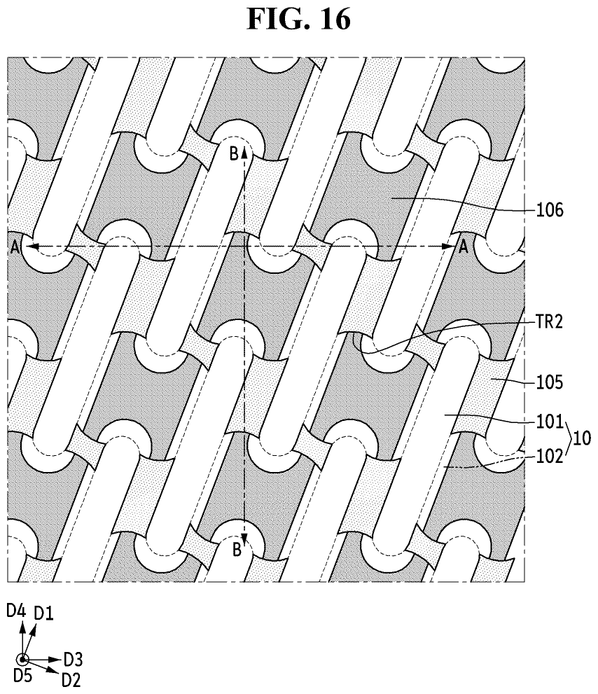

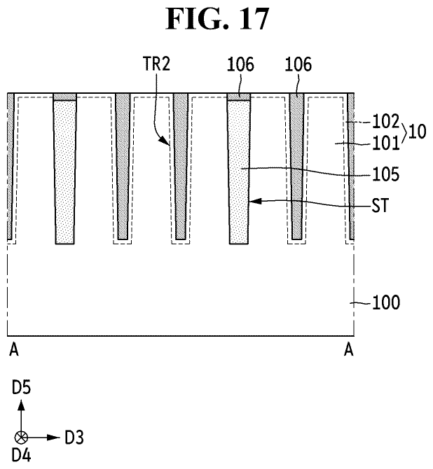

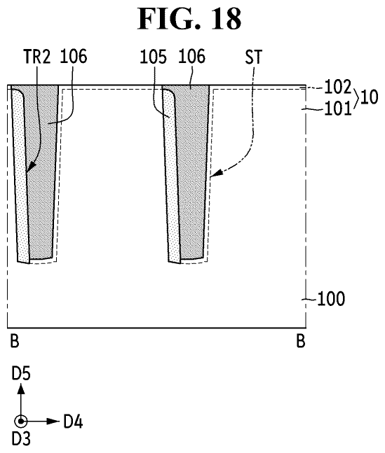

FIGS. 7 through 18 are diagrams illustrating intermediate stages of a method for manufacturing a semiconductor memory device according to some embodiments. For convenience of explanation, differences from the descriptions provided using FIGS. 1 through 6 will be emphasized. FIG. 7 is a layout illustrating active regions, first isolation films, and first trenches. FIG. 8 is a cross-sectional view taken along line A-A of FIG. 7. FIG. 9 is a cross-sectional view taken along line B-B of FIG. 7. FIG. 11 is a cross-sectional view taken along line A-A of FIG. 10. FIG. 12 is a cross-sectional view taken along line B-B of FIG. 10. FIG. 14 is a cross-sectional view taken along line A-A of FIG. 13. FIG. 15 is a cross-sectional view taken along line B-B of FIG. 13. FIG. 16 is a layout illustrating active regions, first isolation films, and second isolation films. FIG. 17 is a cross-sectional view taken along line A-A of FIG. 16. FIG. 18 is a cross-sectional view taken along line B-B of FIG. 16.

Referring to FIGS. 7 through 9, an element isolation trench ST defining first preliminary active regions 101 within a substrate 100 may be formed. The element isolation trench ST may be formed by forming a mask pattern on the substrate 100 and etching the substrate 100 to a predetermined depth, using the mask pattern as an etching mask.

The element isolation trench ST may have a first width between adjacent first preliminary active regions 101 in the first direction D1 and a second width, smaller than the first width, between adjacent first preliminary active regions 101 in the second direction D2. The depth of portions of the element isolation trench ST with the first width may differ from the depth of portions of the element isolation trench ST with the second width. For example, the depth of the portions of the element isolation trench ST with the first width may be greater than the depth of the portions of the element isolation trench ST with the second width.

The first preliminary active regions 101 may have a bar shape with a long axis in the first direction D1. The first preliminary active regions 101 may have a short axis in the second direction D2. The first preliminary active regions 101 may extend lengthwise in the first direction D1 and may be arranged two-dimensionally in the third and fourth directions D3 and D4. From a planar perspective (e.g., from the perspective of the plane including the first, second, third, and fourth directions D1, D2, D3, and D4), the first preliminary active regions 101 may be arranged in a zigzag fashion.

Thereafter, the first isolation films 105 may be formed in the element isolation trench ST. The first isolation films 105 may be formed conformally along the profiles of the upper surfaces of the first preliminary active regions 101 and the element isolation trench ST. The first isolation films 105 may be formed along the sidewalls and bottom surface of the element isolation trench ST.

The first isolation films 105 may conformally cover the upper surfaces of the first preliminary active regions 101 and the profile of the element isolation trench ST. First trenches TR1 may be formed within the element isolation trench ST. The first isolation films 105 may form the first trenches TR1 between adjacent first preliminary active regions 101 in the first direction D1, and between adjacent first preliminary active regions 101 in the second direction D2. In an embodiment, the first isolation films 105 may fill the element isolation trench ST, and then the first trenches TR1 are formed in the first isolation films 105 by partially removing the first isolation films 105. Each first trench TR1 may be placed in a region defined by corresponding four adjacent active regions—two adjacent active regions in the first direction D1 and two adjacent active regions in the second direction D2.

Referring to FIGS. 10 through 12, an expansion process may be performed to expand the first trenches TR1 (from FIG. 7), thereby forming second trenches TR2. The second trenches TR2 may be formed by etching away portions of the first isolation films 105. In an embodiment, the upper surfaces of the first preliminary active regions 101 may be exposed. Portions of the element isolation trench ST may also be exposed. For example, an upper surface of the etched first isolation films 105 may be lower than the upper surfaces of the first preliminary active regions 101. In an embodiment, portions of the first isolation films 105 may be removed through an isotropic etching process such as a wet etching process. For example, a wet etching process may be performed on the first isolation films 105 to expand the first trenches TR1 to the second trenches TR2. Each first trench, surrounded by corresponding four adjacent active regions, may be expanded to a corresponding second trench, and the wet etching process may selectively remove the first isolation films 105 from the corresponding four adjacent first preliminary active regions. The wet etching process may have etch selectivity of the first isolation films 105 with respect to the first preliminary active regions 101.

Portions of the upper surfaces of the first isolation films 105 may not lie in the same plane as the upper surfaces of the first preliminary active regions 101. Portions of the upper surfaces of the first isolation films 105 may be lower than the upper surfaces of the first preliminary active regions 101. In an embodiment, the upper surfaces of the first isolation films 105 may lie in the same plane as at least portions of the upper surfaces of the first preliminary active regions 101.

The second trenches TR2 may be defined by the first preliminary active regions 101 and the first isolation films 105. For example, the second trenches TR2 may be defined by the first preliminary active regions 101 and remaining portions of the first isolation films 105 by the wet etching process. The second trenches TR2 may expose opposite ends of the first preliminary active regions 101 in the first direction D1. The second trenches TR2 may also expose portions of opposite sidewalls of the first preliminary active regions 101 in the second direction D2.

Referring to FIGS. 13 through 15, second preliminary active regions 102 may be epitaxially grown from the first preliminary active regions 101 exposed by the second trenches TR2. For example, opposite ends, in the first direction D1, of each first preliminary active region of the first preliminary active regions 101 and a portion of each side wall of opposite sidewalls, in the second direction D2, of the first preliminary active region 101 may be exposed by the corresponding four adjacent second trenches TR2. Accordingly, active regions 10, including the first preliminary active regions 101 and the second preliminary active regions 102, may be formed. The active regions 10 described above with reference to FIGS. 1 and 2 may be formed.

Referring to FIGS. 16 through 18, second isolation films 106, which fill the second trenches TR2, may be formed. The upper surfaces of the second isolation films 106 may lie in the same plane as the upper surfaces of the active regions 10. Additionally, when the upper surfaces of the first isolation films 105 are positioned lower than the upper surfaces of the active regions 10, the second isolation films 106 may be formed on the first isolation films 105.

Accordingly, isolation films (105 and 106), including the first isolation films 105 and the second isolation films 106, may be formed. The upper surfaces of the isolation films (105 and 106) may lie in the same plane as the upper surfaces of the active regions 10.

Thereafter, referring to FIGS. 1 through 4, gate structures 110 may be formed within the substrate 100 and the isolation films (105 and 106). Bitline structures 140ST may be formed on the gate structures 110. Data storage patterns 190 may be formed on the bitline structures 140ST.

To increase the contact margin between the active regions 10 and the storage contacts 120, it is necessary to increase the length of the active regions 10 in the longitudinal direction, i.e., the first direction D1. However, increasing the length of the active regions 10 in the first direction D1 may result in the corners of the active regions 10 becoming rounded due to the three-dimensional (3D) effect that may arise during the formation of the element isolation trench ST. Therefore, the ends of the active regions 10 may have a convex shape in the longitudinal direction, making it difficult to secure the contact area of the active regions 10 with the storage contacts 120. Moreover, increasing the length of the active regions 10 in the first direction D1 may require increasing the spacing between adjacent active regions 10 in the first direction D1, making it challenging to form an element isolation trench ST with sufficient depth to ensure isolation between the active regions 10.

However, the method for manufacturing a semiconductor memory device according to some embodiments involves forming the first preliminary active regions 101, exposing at least portions of the first preliminary active regions 101 through an expansion process, and forming the second preliminary active regions 102 from the exposed first preliminary active regions 101 to form the active regions 10. For example, the active regions 10 with an increased length in the first direction D1 can be formed without the need to form the element isolation trench ST such that the length of the active region 10 in the first direction D1 increases. Therefore, an element isolation trench ST with sufficient depth for isolating the active regions 10 can be formed, and as the area at opposite ends of the active regions 10 increases, the contact margin between the active regions 10 and the storage contacts 120 can be improved.

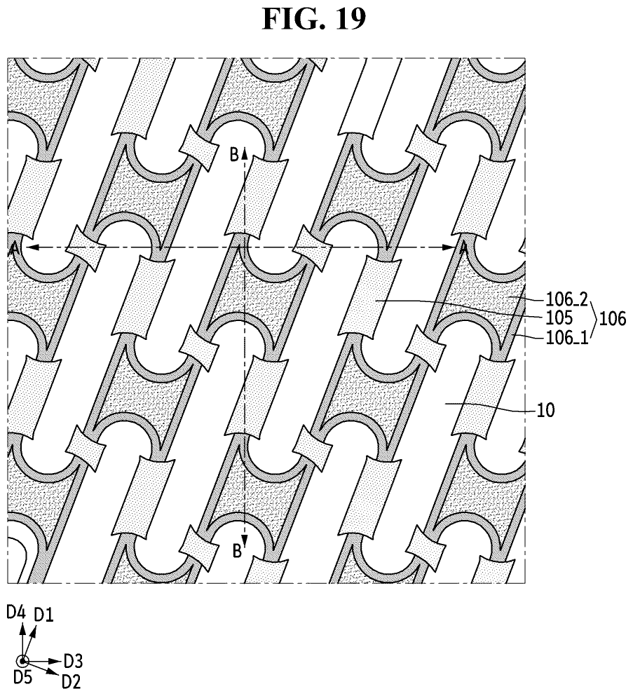

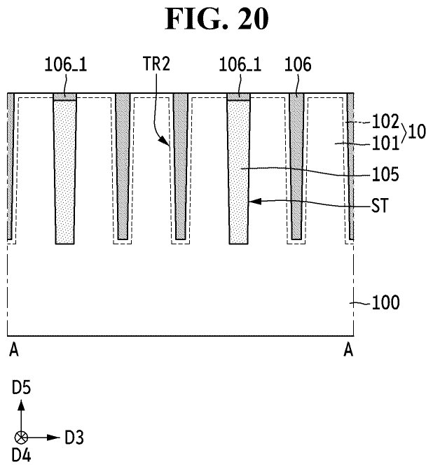

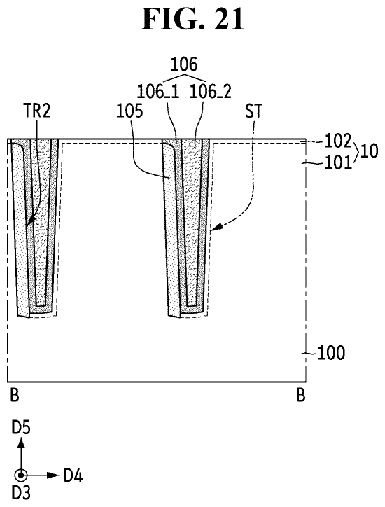

FIGS. 19 through 21 are diagrams illustrating intermediate stages of a method for manufacturing a semiconductor memory device according to some embodiments. FIGS. 19 through 21 may represent steps following those illustrated in FIGS. 13 through 15. FIG. 20 is a cross-sectional view taken along line A-A of FIG. 19, and FIG. 21 is a cross-sectional view taken along line B-B of FIG. 19.

Referring to FIGS. 19 through 21, first films 106_1 extending along the profiles of second trenches TR2 may be formed. Second films 106_2 may fill the second trenches TR2 on the first films 106_1. Accordingly, the second isolation films 106, including the first films 106_1 and the second films 106_2, may be formed. The upper surfaces of the isolation films (105 and 106) may lie in the same plane as the upper surfaces of active regions 10.

Thereafter, referring again to FIGS. 3, 5, and 6, gate structures 110 may be formed within the substrate 100 and the isolation films (105 and 106). Bitline structures 140ST may be formed on the gate structures 110. Data storage patterns 190 may be formed on the bitline structures 140ST.

Although the embodiments of the present disclosure have been described with reference to the accompanying drawings, the present disclosure is not limited to these embodiments and may be manufactured in various other forms. Those skilled in the art will understand that the technical scope or essential characteristics of the present disclosure can be modified and implemented in other specific forms without departing from the spirit of the invention. Therefore, the embodiments described above should be understood as being illustrative in all respects and not limiting.

What is claimed is:

1. A semiconductor memory device comprising:
a substrate provided with a plurality of active regions, wherein each active region of the plurality of active regions extends lengthwise in a first direction; and
an isolation film disposed on the substrate and defining each active region of the plurality of active regions,
wherein each active region of the plurality of active regions includes:
a first expansion and a second expansion, which are opposite to each other in the first direction; and
a connector connecting the first expansion to the second expansion and having a varying width in a second direction perpendicular to the first direction, and
wherein a maximum width, in the second direction, of each of the first expansion and the second expansion is greater than a minimum width, in the second direction, of the connector.

2. The semiconductor memory device of claim 1,
wherein the connector includes:
a body extending lengthwise in the first direction and having the minimum width in the second direction;
a first extension extending from a first side of the body in the second direction; and
a second extension extending from a second side of the body in the second direction, and
wherein the first side and the second side extend in the first direction and are spaced apart from each other in the second direction.

3. The semiconductor memory device of claim 2,
wherein the isolation film includes:
a first portion disposed in a space between the first expansion and the first extension;
a second portion disposed in a space between the first extension and the second expansion;
a third portion disposed in a space between the first expansion and the second extension; and
a fourth portion disposed in a space between the second extension and the second expansion.

4. The semiconductor memory device of claim 2,
wherein a portion of the first extension overlaps a portion of the second extension in the second direction.

5. The semiconductor memory device of claim 2,
wherein the isolation film includes:
a first isolation film contacting a portion of the first side of the body and a portion of the second side of the body; and
a second isolation film contacting an outer sidewall of the first extension and an outer sidewall of the second extension.

6. The semiconductor memory device of claim 5,
wherein the second isolation film is a single layer.

7. The semiconductor memory device of claim 5,
wherein the second isolation film is a multilayer.

8. The semiconductor memory device of claim 2,
wherein each of the first expansion and the second expansion has a convex surface.

9. The semiconductor memory device of claim 1, further comprising:
a plurality of data storage patterns on the substrate; and
a pair of buried contacts electrically connecting the first expansion and the second expansion to a pair of data storage patterns among the plurality of data storage patterns.

10. The semiconductor memory device of claim 1, further comprising:
a plurality of bitlines arranged in a third direction and extending in a fourth direction different from the first direction and the second direction, wherein the plurality of bitlines are disposed on the substrate, and the third direction is perpendicular to the fourth direction; and
a plurality of direct contacts electrically connecting the plurality of bitlines to the substrate.

11. The semiconductor memory device of claim 1, further comprising:
a plurality of wordlines extending in a third direction different from the first direction and the second direction, wherein the plurality of wordlines are disposed on the substrate and are arranged in a fourth direction perpendicular to the third direction,
wherein, for a first active region of the plurality of active regions, corresponding two adjacent wordlines among the plurality of wordlines overlap the first active region and are spaced apart from a first expansion and a second expansion of the first active region when viewed in a plan view.

12. A semiconductor memory device comprising:
a substrate provided with a plurality of active regions, wherein each active region of the plurality of active regions extends lengthwise in a first direction,
wherein each active region of the plurality of active regions includes:
a first expansion and a second expansion, which are opposite to each other in the first direction; and
a connector connecting the first expansion to the second expansion and having a varying width in a second direction perpendicular to the first direction,
wherein the connector includes:
a first portion connected to the first expansion;
a second portion connected to the second expansion; and
a third portion between the first portion and the second portion, and
wherein a width, in the second direction, of the third portion is greater than a width of each of the first portion and the second portion.

13. The semiconductor memory device of claim 12,
wherein each of the first expansion and the second expansion protrudes convexly from the connector in the first direction.

14. The semiconductor memory device of claim 12,
wherein a maximum width, in the second direction, of each of the first expansion and the second expansion is greater than a minimum width, in the second direction, of the connector.

15. The semiconductor memory device of claim 12, further comprising:
a pair of data storage patterns on each active region of the plurality of active regions the substrate; and
a pair of buried contacts electrically connecting the first expansion and the second expansion and the pair of data storage patterns.

16. The semiconductor memory device of claim 12, further comprising:
a plurality of wordlines extending in a third direction different from the first direction and the second direction,
wherein the plurality of wordlines are disposed within the substrate and are arranged in a fourth direction perpendicular to the third direction, and
wherein, for a first active region of the plurality of active regions, corresponding two adjacent wordlines among the plurality of wordlines overlap the first active region and are spaced apart from a first expansion and a second expansion of the first active region when viewed in a plan view.

17. The semiconductor memory device of claim 12,
wherein the connector further includes:
a fourth portion connecting the first portion and the third portion; and
a fifth portion connecting the second portion and the third portion, and
wherein a width, in the second direction, of each of the fourth portion and the fifth portion is greater than the width of each of the first portion and the second portion.

18. The semiconductor memory device of claim 17,
wherein the width, in the second direction, of the third portion is greater than the width of each of the fourth portion and the fifth portion.

19. A semiconductor memory device comprising:
a substrate provided with a plurality of active regions, wherein each active region of the plurality of active regions has a long axis in a first direction and a short axis in a second direction perpendicular to the first direction;
an isolation film disposed on the substrate and defining each active region of the plurality of active regions;
a plurality of wordlines disposed within the substrate and extending in a third direction;
a plurality of bitlines disposed on the substrate and extending in a fourth direction perpendicular to the third direction; and
a plurality of data storage patterns on the substrate,
wherein each active region of the plurality of active regions includes:
a first expansion and a second expansion, which are opposite to each other in the first direction; and
a connector connecting the first expansion to the second expansion and having a varying width in the second direction,
wherein when viewed in a plan view, each of the first expansion and the second expansion has a semicircular shape,
wherein at a boundary between the first expansion and the connector, a width, in the second direction, of the first expansion is greater than a width, in the second direction, of the connector,
wherein at a boundary between the second expansion and the connector, a width, in the second direction, of the second expansion is greater than the width, in the second direction, of the connector, and
wherein for a first active region of the plurality of active regions, corresponding two data storage patterns among the plurality of data storage patterns are electrically connected to a first expansion and a second expansion of the first active region.

20. The semiconductor memory device of claim 19,
wherein, for the first active region of the plurality of active regions, corresponding two adjacent wordlines among the plurality of wordlines overlap the first active region and are spaced apart from the first expansion and the second expansion of the first active region when viewed in the plan view.
